(19) United States
(12) Patent Application Publication
(10) Pub. No.: US 2009/0194143 A1
(43) Pub. Date: Aug. 6, 2009

(54) Photovoltaic Arrays, Systems and Roofing Elements Having Parallel-Series Wiring Architectures

(76) Inventors: Gregory F. Jacobs, Oreland, PA (US); Wayne E. Shaw, Glen Mills, PA (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/359,978

(22) Filed: Jan. 26, 2009

Related U.S. Application Data
(60) Provisional application No. 61/023,610, filed on Jan. 25, 2008.

(51) Int. Cl. H01L 31/042; E04D 13/18; B23P 15/26

(52) U.S. Cl. 136/244; 52/173.3; 29/890.033

(57) ABSTRACT

The present invention relates generally to the photovoltaic generation of electrical energy. The present invention relates more particularly to photovoltaic arrays, systems and roofing products in which a plurality of photovoltaic elements are electrically interconnected. One aspect of the present invention is a photovoltaic array including a plurality of pods of photovoltaic elements, the pods being electrically interconnected in series, each pod comprising a plurality of photovoltaic elements electrically interconnected in parallel, the photovoltaic elements of each pod having voltages within 20% of one another and at least one photovoltaic element of each pod having an amperage at least 20% greater than the amperage of another photovoltaic element of the pod.

### CROSS-REFERENCE TO RELATED APPLICATIONS

This application claims priority under 35 U.S.C. § 119(e) to U.S. Provisional Patent Applications Ser. No. 61/023,610, filed Jan. 25, 2008, which is hereby incorporated herein by reference in its entirety.

### BACKGROUND OF THE INVENTION

1. Field of the Invention

The present invention relates generally to the photovoltaic generation of electrical energy. The present invention relates more particularly to photovoltaic arrays, systems and roofing products in which a plurality of photovoltaic elements are electrically interconnected.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as device performance has improved. They can be used to provide at least a significant fraction of the electrical energy needed for a building's overall function; or they can be used to power one or more particular devices, such as exterior lighting systems. Photovoltaic cells are often provided as photovoltaic elements in which a plurality of photovoltaic cells are electrically interconnected.

Aesthetically integrating photovoltaic media with a roof surface can be challenging. Acceptable aesthetics can be especially necessary for photovoltaic systems that are to be installed on a residential roof, as residential roofs tend to have relatively high slopes (e.g., > 4/12) and are therefore visible from ground level, and homeowners tend to be relatively sensitive to the aesthetic appearance of their homes. Electrical considerations militate toward the use of identical photovoltaic elements in a photovoltaic system. Unfortunately, use of identical photovoltaic elements greatly limits the system designer's efforts in providing an aesthetically acceptable system.

There remains a need for photovoltaic arrays, systems and roofing products that address these deficiencies.

### SUMMARY OF THE INVENTION

One aspect of the present invention is a photovoltaic array including a plurality of pods of photovoltaic elements, the pods being electrically interconnected in series, each pod comprising a plurality of photovoltaic elements electrically interconnected in parallel, the photovoltaic elements of each pod having voltages within 20% of one another and at least one photovoltaic element of each pod having an amperage at least 20% greater than the amperage of another photovoltaic element of the pod.

Another aspect of the present invention is a photovoltaic system including a plurality of photovoltaic arrays electrically interconnected in series, each photovoltaic array including a plurality of pods of photovoltaic elements, the pods being electrically interconnected in series, each pod comprising a plurality of photovoltaic elements electrically interconnected in parallel, the photovoltaic elements of each pod having voltages within 20% of one another and at least one photovoltaic element of each pod having an amperage at least 20% greater than the amperage of another photovoltaic element of the pod.

Another aspect of the invention is a photovoltaic roofing element including a roofing substrate; and at least one pod of photovoltaic elements, each pod comprising a plurality of photovoltaic elements disposed on the roofing substrate and electrically interconnected in parallel, the photovoltaic elements of each pod having voltages within 20% of one another and at least one photovoltaic element of each pod having an amperage at least 20% greater than the amperage of another photovoltaic element of the pod.

Another aspect of the invention is a photovoltaic roofing array including a plurality of photovoltaic roofing elements electrically interconnected in series, each including a roofing substrate; and at least one pod of photovoltaic elements, each pod comprising a plurality of photovoltaic elements disposed on the roofing substrate and electrically interconnected in parallel, the photovoltaic elements of each pod having voltages within 20% of one another and at least one photovoltaic element of each pod having an amperage at least 20% greater than the amperage of another photovoltaic element of the pod.

Another aspect of the invention is a photovoltaic roofing system comprising a plurality of photovoltaic roofing arrays, each including a plurality of photovoltaic roofing elements electrically interconnected in series, each including a roofing substrate; and at least one pod of photovoltaic elements, each pod comprising a plurality of photovoltaic elements disposed on the roofing substrate and electrically interconnected in parallel, the photovoltaic elements of each pod having voltages within 20% of one another and at least one photovoltaic element of each pod having an amperage at least 20% greater than the amperage of another photovoltaic element of the pod.

The arrays, systems and roofing elements of the present invention can result in a number of advantages. For example, in certain aspects the present invention allows the use of groups of photovoltaic elements having different size, shape, appearance and/or output rating to achieve efficient generation of electrical power. Moreover, in certain aspects the present invention provides a high degree of design flexibility, enabling a wide range of roofing product and photovoltaic array or system design possibilities. Other advantages will be apparent to the person of skill in the art.

The accompanying drawings are not necessarily to scale, and sizes of various elements can be distorted for clarity.

### BRIEF DESCRIPTION OF THE DRAWINGS

FIG. 1 is a schematic view of a photovoltaic array according to one embodiment of the invention;

FIG. 2 is a schematic exploded view and schematic cross sectional view of a photovoltaic element suitable for use in the present invention;

FIG. 3 is a schematic view of a photovoltaic system according to one embodiment of the invention;

FIG. 4 is a schematic view of a photovoltaic roofing element according to one embodiment of the invention;

FIG. 5 is a schematic view of a photovoltaic array according to one embodiment of the invention;

FIG. 6 is a schematic view of a photovoltaic array according to another embodiment of the invention;

FIG. 7 is a schematic view of a photovoltaic roofing element according to one embodiment of the invention; and

FIG. 8 is a schematic view of a photovoltaic array according to one embodiment of the invention.

### DETAILED DESCRIPTION OF THE INVENTION

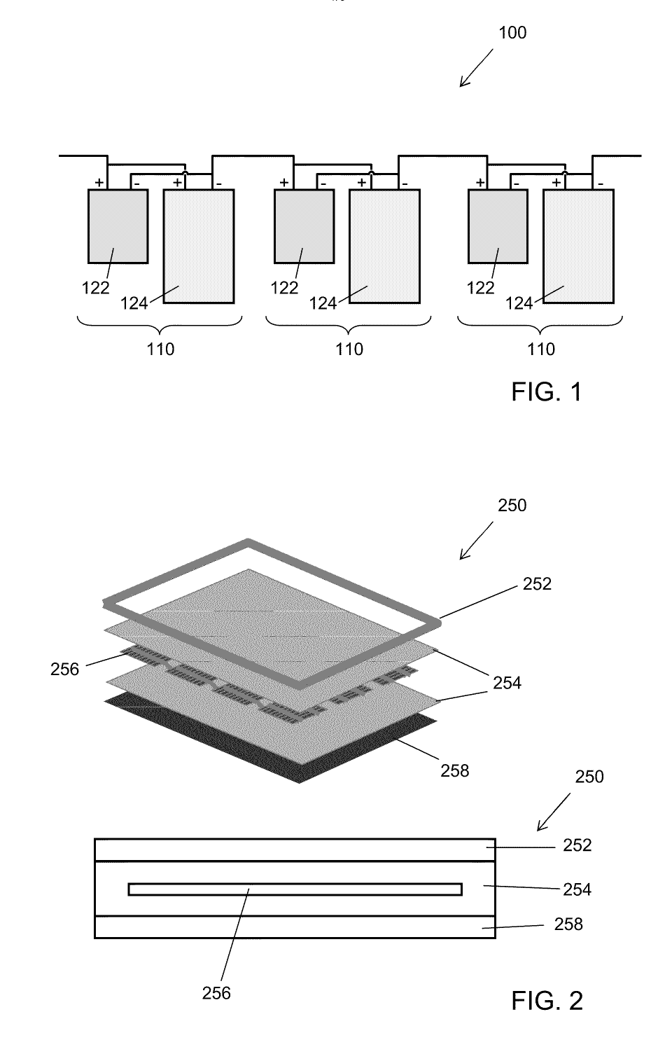

One embodiment of a photovoltaic array according to one aspect of the invention is shown in schematic view in FIG. 1. Photovoltaic array 100 comprises a plurality of pods 110 of photovoltaic elements. As used herein, a “pod” of photovoltaic elements is a grouping of a plurality of photovoltaic elements. Each pod 110 comprises a plurality of photovoltaic elements 122, 124. In each pod, the photovoltaic elements 122, 124 are electrically interconnected in parallel. The “+” and “−” symbols denote the positive and negative electrical terminals of the photovoltaic elements. Parallel interconnection within each pod allows the build-up of current, so that the output amperage of each pod approximates the sum of the individual amperages of its individual photovoltaic elements. In each pod, the photovoltaic elements have voltages within 20% of one another, and at least one photovoltaic element has an amperage at least 20% greater than the amperage of another photovoltaic element of the pod. The voltages and amperages are the output voltages and amperages of the photovoltaic elements, compared under the same solar irradiation conditions. The individual pods 110 are electrically interconnected in series. The series interconnection of the pods allows for the build-up of voltage, so that the output voltage of the array approximates the sum of the output voltages of the individual pods.

Photovoltaic elements suitable for use in the various aspects of the present invention comprise one or more interconnected photovoltaic cells provided together in a single package. The photovoltaic cells of the photovoltaic elements can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide and copper indium gallium selenide. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of photovoltaic elements for use in the present invention. In one embodiment of the invention, the photovoltaic element includes a monocrystalline silicon photovoltaic cell or a polycrystalline silicon photovoltaic cell. The photovoltaic elements for use in the present invention can be flexible, or alternatively can be rigid.

The photovoltaic elements can be encapsulated photovoltaic elements, in which photovoltaic cells are encapsulated between various layers of material. For example, an encapsulated photovoltaic element can include a top layer material at its top surface, and a bottom layer material at its bottom surface. The top layer material can, for example, provide environmental protection to the underlying photovoltaic cells, and any other underlying layers. Examples of suitable materials for the top layer material include fluoropolymers, for example ETFE (“TEFZEL”), PFE, FEP, PVF (“TEDLAR”), PCTFE or PVDF. The top layer material can alternatively be, for example, a glass sheet, or a non-fluorinated polymeric material. The bottom layer material can be, for example, a fluoropolymer, for example ETFE (“TEFZEL”), PFE, FEP, PVDF or PVF (“TEDLAR”). The bottom layer material can alternatively be, for example, a polymeric material (e.g., polyester such as PET); or a metallic material (e.g., steel or aluminum sheet).

As the person of skill in the art will appreciate, an encapsulated photovoltaic element can include other layers interspersed between the top layer material and the bottom layer material. For example, an encapsulated photovoltaic element can include structural elements (e.g., a reinforcing layer of glass, metal or polymer fibers, or a rigid film); adhesive layers (e.g., EVA to adhere other layers together); mounting structures (e.g., clips, holes, or tabs); one or more electrical connectors (e.g., electrodes, electrical connectors; optionally connectorized electrical wires or cables) for electrically interconnecting the photovoltaic cell(s) of the encapsulated photovoltaic element with an electrical system. An example of an encapsulated photovoltaic element suitable for use in the present invention is shown in schematic exploded view and schematic cross sectional view in FIG. 2. Encapsulated photovoltaic element 250 includes a top protective layer 252 (e.g., glass or a fluoropolymer film such as ETFE, PVDF, PVF, FEP, PFA or PCTFE); encapsulant layers 254 (e.g., EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells 256; and a backing layer 258 (e.g., PVDF, PVF, PET).

The photovoltaic element can include at least one antireflection coating, for example as the top layer material in an encapsulated photovoltaic element, or disposed between the top layer material and the photovoltaic cells.

Suitable photovoltaic elements can be obtained, for example, from China Electric Equipment Group of Nanjing, China, as well as from several domestic suppliers such as Uni-Solar Ovonic, Sharp, Shell Solar, BP Solar, USFC, FirstSolar, General Electric, Schott Solar, Evergreen Solar and Global Solar. Moreover, the person of skill in the art can fabricate encapsulated photovoltaic elements using techniques such as lamination or autoclave processes. Encapsulated photovoltaic elements can be made, for example, using methods disclosed in U.S. Pat. No. 5,273,608, which is hereby incorporated herein by reference.

The photovoltaic element also has an operating wavelength range. Solar radiation includes light of wavelengths spanning the near UV, the visible, and the near infrared spectra. As used herein, the term “solar radiation,” when used without further elaboration means radiation in the wavelength range of 300 nm to 2500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the photovoltaic element falls within the range of about 300 nm to about 1200 nm.

In certain embodiments of the invention, the photovoltaic elements of each pod have voltages within 10% of one another. For example, in one preferred embodiment, the photovoltaic elements of each pod have voltages within 5% of one another.

In certain embodiments of the invention, at least one photovoltaic element of each pod has an amperage at least 50% greater than the amperage of another photovoltaic element of the pod.

In certain embodiments of the invention, the pods have amperages within 20% of one another. For example, in one embodiment, the pods have amperages within 10% of one another.

In the example of FIG. 1, each pod has two photovoltaic elements. Of course, other numbers of photovoltaic elements can be used in each pod (e.g., in the range of 2-12, or even in the range of 2-8). One factor in determining the maximally desirable number of photovoltaic elements in each pod is the increased wire size that would be necessary with increased built-up currents. With the relatively low amperage of currently-available photovoltaic elements, #12 wire will often be sufficient to interconnect up to several photovoltaic elements within each pod. Moreover, while higher built-up currents may require larger gauge (and more costly) wire, because the photovoltaic elements are fairly well-contained within the pod, it is not expected that the amount of heavy gauge wire would be excessive with respect to the overall system, and only a small portion of the current load would traverse the array at higher amperages.

One advantage of the photovoltaic array described above is that it can integrate photovoltaic elements of different amperages into an electrically-efficient photovoltaic system. The design flexibility with respect to the amperages of the individual photovoltaic elements can allow the designer to use a variety of types of photovoltaic elements together in a single system, without suffering the limitation in current that results when interconnecting photovoltaic elements of different amperages in series.

In certain embodiments, the photovoltaic elements of differing amperages differ from one another in visual appearance. For example, the photovoltaic elements of differing amperages can have different colors, different patterns and/or surface textures. Different color can result from the use of different photovoltaic materials; for example colors ranging from blue to black are currently commercially available. In other embodiments, one or more of the photovoltaic elements includes a colored and/or patterned overlay film that provides a desired visual appearance to the photovoltaic element (e.g., a desired color, texture, pattern, image or variegation). The overlay film has sufficient transparency in the wavelength range of solar radiation so as to allow adequate photovoltaic power generation. In other embodiments, the appearance of a photovoltaic element can be adjusted using colored, textured or patterned layers in the construction of the photovoltaic element. Methods for adjusting the appearance of photovoltaic elements are described, for example, in U.S. Provisional Patent Applications Ser. No. 60/946,881 and 61/019,740, and U.S. patent applications Ser. Nos. 11/456,200, 11/742,909, 12/145,166, 12/266,481 and 12/267,458 each of which is hereby incorporated herein by reference.

In some embodiments of the invention, the total color difference ΔE* between the photovoltaic elements differing in amperage is at least 10, or even at least 20. As used herein L*, a* and b* are the color measurements for a given sample using the 1976 CIE color space. The strength in color space E* is defined as E*=(L*²+a*²+b*²)^{1/2}. The total color difference ΔE* between two articles is defined as ≢E*=(ΔL*²+Δa*²+Δb*²)^{1/2}, in which ΔL*, Δa* and Δb* are respectively the differences in L*, a* and b* for the two articles. L*, a* and b* values are measured using a HunterLab Model Labscan XE spectrophotometer using a 0° viewing angle, a 45° illumination angle, a 10° standard observer, and a D-65 illuminant. Lower L* values correspond to relatively darker tones.

The photovoltaic array can be provided in a number of architectures. For example, the photovoltaic array can be provided as part of a stand-alone photovoltaic module. In other embodiments, the photovoltaic array can be provided as a series of electrically-interconnected photovoltaic elements that lay upon an existing roof. In other embodiments, and as described in more detail below, the photovoltaic array can be provided as photovoltaic elements integrated with roofing materials (i.e., as photovoltaic roofing elements). The individual photovoltaic elements of a pod can be disposed on the same roofing substrate, or on different roofing substrates.

In certain embodiments, the photovoltaic elements of differing amperages have different sizes. For example, the photovoltaic elements can have similar visual appearance, but be of different sizes, such as a T-cell (12 cm×18 cm) and an L-cell (24 cm×36 cm), available from UniSolar Ovonic.

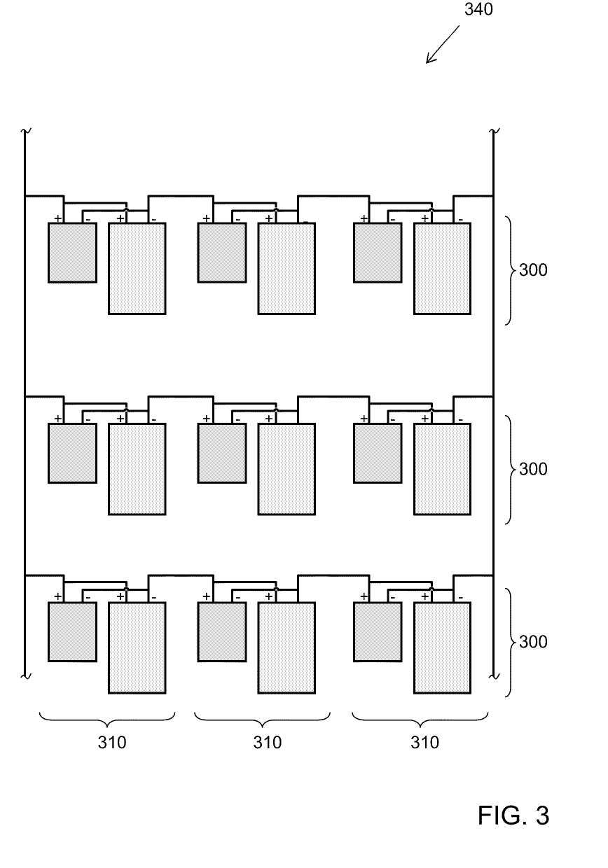

Another embodiment of the invention is shown in schematic view in FIG. 3. Photovoltaic system 340 comprises two or more photovoltaic arrays 300 as described above, electrically interconnected in parallel. The arrays can be configured (e.g., with a desired number of series-connected pods 310) to provide a desired output voltage. Electrical interconnection of the arrays in parallel allows the build-up of current. The photovoltaic system can be interconnected with an inverter to allow photovoltaically-generated electrical power to be used on-site, stored in a battery, or introduced to an electrical grid. In certain embodiments, the amperages of the photovoltaic arrays are within 20% of one another, or even within 10% of one another.

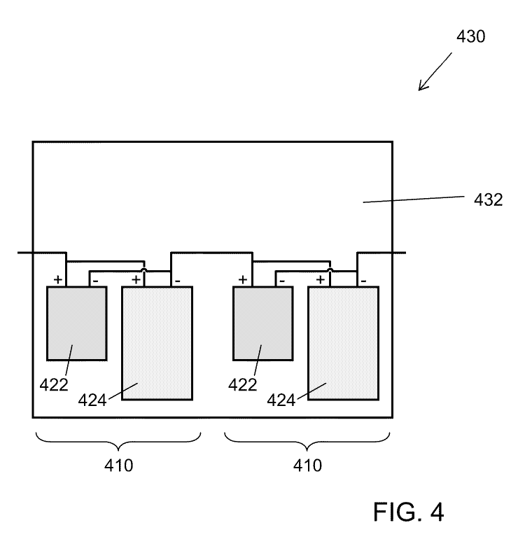

Another embodiment of the invention is shown in top schematic view in FIG. 4. Photovoltaic roofing element 430 includes roofing substrate 432 and at least one pod 410 of photovoltaic elements. Each pod 410 comprises a plurality of photovoltaic elements (422, 424) disposed on the roofing substrate 432 and electrically interconnected in parallel. The photovoltaic elements of each pod have voltages within 20% of one another, and at least one photovoltaic element of each pod has an amperage at least 20% greater than the amperage of another photovoltaic element of the pod.

The present invention can be practiced using any of a number of types of roofing substrates. The roofing substrate can be, for example, a bituminous shingle (e.g., a granule-coated asphalt shingle), or a bituminous roofing membrane. In other embodiments, the roofing substrate is a roofing panel (e.g., made from polymer or metal). In certain embodiments of the invention, the roofing substrate is formed from a polymeric material. Suitable polymers include, for example, polyolefin, polyethylene, polypropylene, ABS, PVC, polycarbonates, nylons, EPDM, TPO, fluoropolymers, silicone, rubbers, thermoplastic elastomers, polyesters, PBT, poly(meth)acrylates, epoxies, and can be filled or unfilled or formed. The polymeric roofing substrate can be, for example, a polymeric tile, shake or shingle. In other embodiments, the polymeric roofing substrate can be a polymeric roofing membrane. The roofing substrate can be made of other materials, such as composite, ceramic, or cementitious materials. The manufacture of photovoltaic roofing elements using a variety of roofing substrates are described, for example, in U.S. patent application Ser. Nos. 12/146,986, 12/266,409, 12/268,313, 12/351,653, and 12/339,943, and U.S. Patent Application Publication no. 2007/0266562, each of which is hereby incorporated herein by reference in its entirety.

In the example of FIG. 4, the photovoltaic roofing element comprises two pods interconnected in series. Certain photovoltaic roofing elements according to the invention include two or more pods (e.g., in the range of 3-12 pods) of photovoltaic elements, the pods being interconnected in series. The pods can have, for example, amperages within 20% of one another.

For example, in the example of FIG. 4, if the photovoltaic elements 422 have a voltage of 1.5 V and an amperage of 1 A, and the photovoltaic elements 424 have a voltage of 1.5 V and an amperage of 3 A, then the output for each pod 410 is 1.5 V and 4 A, and the total output of the photovoltaic roofing element 430 is 3 V and 4 A, for a total power of 12 W.

In still other embodiments of the invention, the photovoltaic roofing element has only a single pod of photovoltaic elements.

In certain embodiments of the invention, the photovoltaic elements of each pod have voltages within 10% of one another. For example, in one preferred embodiment, the photovoltaic elements of each pod have voltages within 5% of one another.

In certain embodiments of the invention, at least one photovoltaic element of each pod has an amperage at least 50% greater than the amperage of another photovoltaic element of the pod.

In certain embodiments of the invention, the pods have amperages within 20% of one another. For example, in one embodiment, the pods have amperages within 10% of one another.

As described above with respect to the photovoltaic arrays of the present invention, the photovoltaic elements of differing amperages can differ from one another in visual appearance. For example, the photovoltaic elements of differing amperages can have different colors, different patterns and/or different surface textures. Similarly, the photovoltaic elements of differing amperages can have different sizes.

Another embodiment of the invention is a photovoltaic roofing array including a plurality of photovoltaic roofing elements as described above. The photovoltaic roofing elements are electrically interconnected in series as described above with reference to the photovoltaic arrays of the present invention. A photovoltaic roofing system according to the present invention includes a plurality of photovoltaic roofing arrays electrically interconnected in parallel as described above with reference to the photovoltaic systems of the present invention. In certain embodiments, the amperages of the photovoltaic roofing arrays are within 20% of one another, or even within 10% of one another.

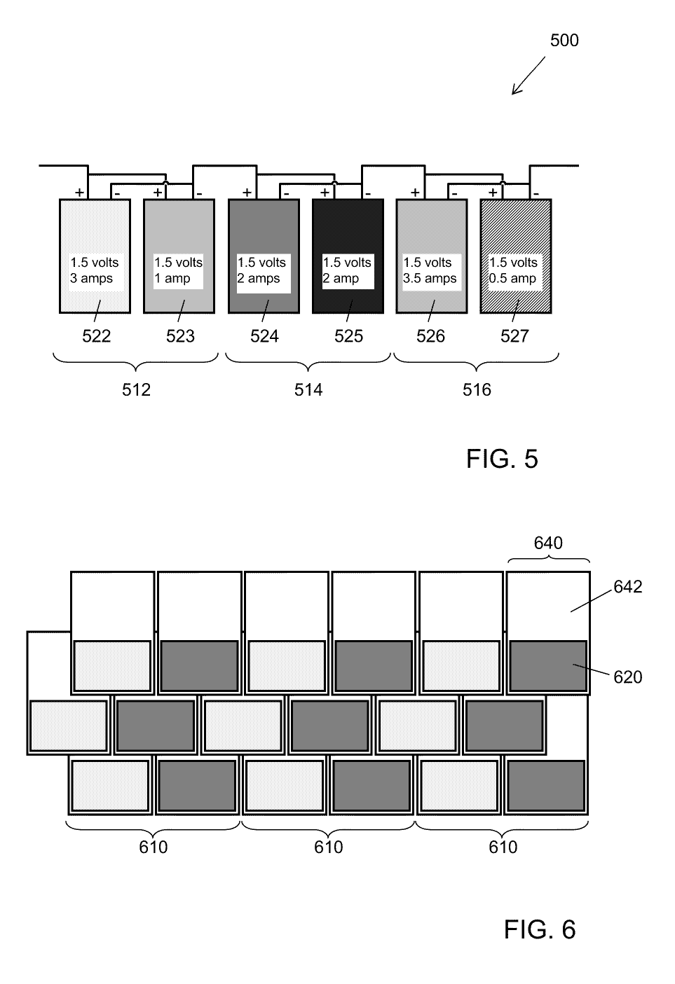

In the embodiments described above, the pods of an array or of a photovoltaic roofing element are configured identically. In other embodiments, at least one pod of an array or of a photovoltaic roofing element is configured substantially differently than another pod. For example, in the photovoltaic array 500 of FIG. 5, pods 512, 514 and 516 are configured differently from one another. Each of the photovoltaic elements 522, 523, 524, 525, 526 and 527 has a voltage of 1.5 V. In pod 512, photovoltaic element 522 has an amperage of 3 A, and photovoltaic element 523 has an amperage of 1 A, resulting in pod 512 having a voltage of 1.5 V and an amperage of 4 A. In pod 514, photovoltaic element 524 has an amperage of 2 A, and photovoltaic element 525 has an amperage of 2 A, resulting in pod 514 having a voltage of 1.5 V and an amperage of 4 A. In pod 516, photovoltaic element 526 has an amperage of 3.5 A, and photovoltaic element 525 has an amperage of 0.5 A, resulting in pod 516 having a voltage of 1.5 V and an amperage of 4 A. This array has a total output of 18 W at 4.5 V and 4 A. Use of differently-configured pods in an array or a photovoltaic roofing element allows the designer to provide a wide range of colors and patterns, for example, by providing more degrees of freedom to match or complement the color and patterns of a wide variety of roofing materials (e.g., the roofing substrate(s) on which the pods are disposed and/or surrounding roofing materials). Such an arrangement can be beneficial, for example, when it is desired to use only a limited amount of roof space (e.g., 3 SQ) for the installation of photovoltaic roofing elements, while the remaining roof space (e.g., 6 SQ) is covered with standard roofing elements (e.g., shingles).

The individual photovoltaic elements of a pod can be disposed on the same roofing element, as described above with reference to FIG. 4. In other embodiments, the individual photovoltaic elements of a pod can be on different roofing elements. For example, as shown in FIG. 6, each photovoltaic roofing element 640 includes a photovoltaic element 620 disposed on roofing substrate 642 (e.g., a polymeric roofing tile). Each pod 610 includes photovoltaic elements of two different photovoltaic roofing elements.

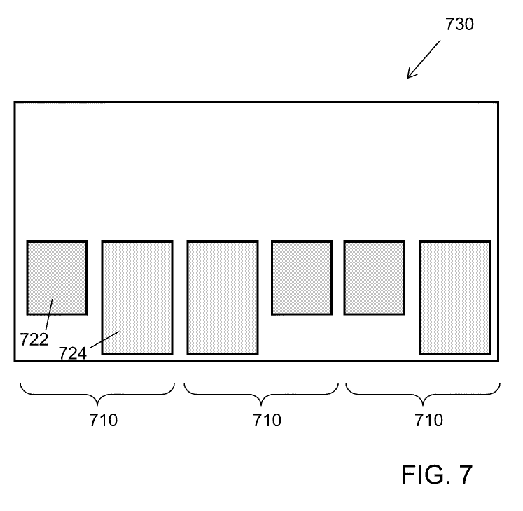

FIG. 7 presents another configuration for a photovoltaic roofing element according to the present invention. In FIG. 7, the electrical interconnections are omitted for clarity. Photovoltaic roofing element 730 with three pods 710 of photovoltaic elements, each pod having a smaller photovoltaic element 722 with a lower amperage, and a larger photovoltaic element 724 with a higher amperage. The order of the photovoltaic elements within the pods are varied along the photovoltaic roofing element. In this manner, a more random variegated appearance of a roof can be obtained. Of course, the person of skill in the art will understand that only a few of the many, many possible configurations have been specifically described herein. It will be apparent that a wide variety of different arrangements of photovoltaic elements could be used in practicing the present invention.

Electrical interconnections can be made in a variety of ways in the systems, arrays and roofing elements of the present invention. The photovoltaic elements can be provided with electrical connectors (e.g., available from Tyco International), which can be connected together to provide the desired interconnections. In other embodiments, the photovoltaic elements can be wired together using lengths of electrical cable. Electrical connections are desirably made using cables, connectors and methods that meet UNDERWRITERS LABORATORIES and NATIONAL ELECTRICAL CODE standards. Electrical connections are described in more detail, for example, in U.S. patent application Ser. Nos. 11/743,073 12/266,498 and 12/268,313, and U.S. Provisional Patent Application Ser. No. 61/121,130 each of which is incorporated herein by reference in its entirety. The wiring system can also include return path wiring (not shown), as described in U.S. Provisional Patent Application Ser. No. 61/040,376, which is hereby incorporated herein by reference in its entirety.

In certain embodiments of the invention a plurality of photovoltaic roofing elements according to the invention are disposed on a roof deck and electrically interconnected. There can be one or more layers of material (e.g. underlayment), between the roof deck and the photovoltaic roofing elements of the present invention. The photovoltaic roofing elements of the present invention can be installed on top of an existing roof, in such embodiments, there would be one or more layers of standard (i.e., non-photovoltaic) roofing elements (e.g., asphalt coated shingles) between the roof deck and the photovoltaic roofing elements of the present invention. Even when the photovoltaic roofing elements of the present invention are not installed on top of preexisting roofing materials, the roof can also include one or more standard roofing elements, for example to provide weather protection at the edges of the roof, or in areas not suitable for photovoltaic power generation.

Another embodiment of the invention relates to a method of assembling a photovoltaic array. The method includes first assembling a plurality of pods of photovoltaic elements, each pod being assembled by electrically interconnecting a plurality of photovoltaic elements in parallel, the photovoltaic elements of each pod having voltages within 20% of one another and at least one photovoltaic element of each pod having an amperage at least 20% greater than the amperage of another photovoltaic element of the pod, as described above. The pods can be as described above. The pods are then electrically interconnected in series. The electrical interconnection in series can be performed, for example, after the pods are installed, for example, on a roof. A method of assembling a photovoltaic system according to one embodiment of the present invention includes electrically interconnecting the photovoltaic arrays in parallel. The photovoltaic arrays and systems made according to these embodiments of the invention can, for example, be disposed on a roof.

Another embodiment of the invention relates to a method of assembling a photovoltaic roofing element. The method includes disposing one or more pluralities of photovoltaic elements on a roofing substrate; and electrically interconnecting the one or more pluralities of photovoltaic elements into one or more pods of photovoltaic elements, each pod comprising a plurality of photovoltaic elements disposed on the roofing substrate and electrically interconnected in parallel, the photovoltaic elements of each pod having voltages within 20% of one another and at least one photovoltaic element of each pod having an amperage at least 20% greater than the amperage of another photovoltaic element of the pod. The electrical interconnection can be performed before, after, or at the same time as the one or more pluralities of photovoltaic elements are disposed on the roofing substrate. The photovoltaic elements can be disposed on the roofing substrate before it is installed on the roof, or after. The pods can be electrically interconnected in series to form photovoltaic roofing arrays.

Another embodiment of the invention is a kit for the assembly of a photovoltaic roofing system. The kit includes a plurality of roofing substrates, for example as described above, and one or more pluralities of photovoltaic elements, the photovoltaic elements of each plurality having voltages within 20% of one another and at least one photovoltaic element of each plurality having an amperage at least 20% greater than the amperage of another photovoltaic element of the plurality. The kit also includes an electrical connection system sufficient to electrically interconnect the one or more pluralities of photovoltaic elements into one or more pods of photovoltaic elements, the photovoltaic elements of each pod having voltages within 20% of one another and at least one photovoltaic element of each pod having an amperage at least 20% greater than the amperage of another photovoltaic element of the pod, as described above; and sufficient to electrically interconnect the one or more pods in series. The electrical connection system can be integral to the photovoltaic elements (e.g., as connectors and electrical cables attached to the photovoltaic elements) and/or the roofing substrates (e.g., as connectors and electrical cables attached to the roofing substrates); or can be provided as separate components.

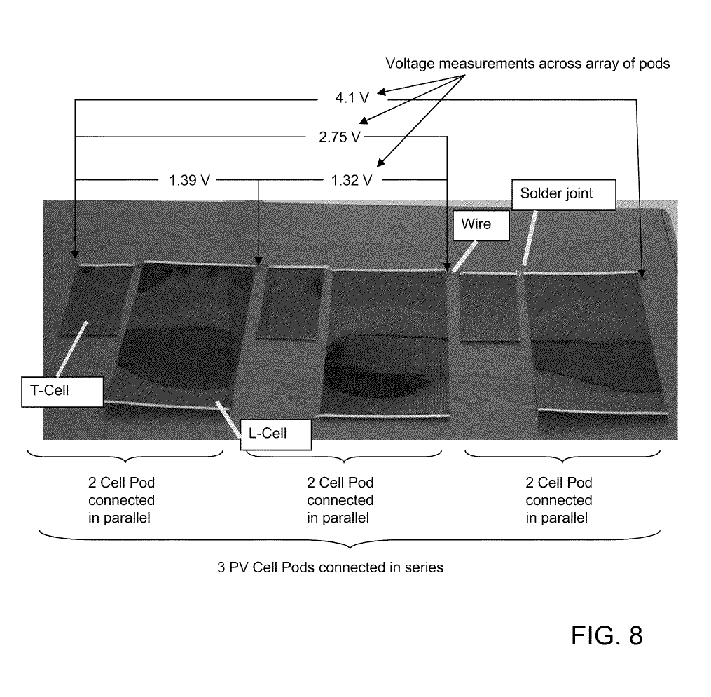

FIG. 8 is a photograph of an array of 3 pods of photovoltaic elements connected in series. Each pod includes one L-Cell and one T-Cell (UniSolar Ovonic) connected in parallel using standard wire and solder connections. Voltages were measured across various points in the array using. The voltage measured across the first pod was 1.39 V. The voltage measured across the second pod was 1.32 V. The voltage measured across the series-connected first and second pods was 2.75 V. The voltage measured across all three series-connected pods was 4.10 V. The output current, and therefore the output power, of this array would be substantially higher than the output current of an analogous array of series-connected photovoltaic elements, as a result of the parallel-series interconnection scheme of the present invention.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

What is claimed is:

1. A photovoltaic array comprising:
a plurality of pods of photovoltaic elements, the pods being electrically interconnected in series, each pod comprising a plurality of photovoltaic elements electrically interconnected in parallel, the photovoltaic elements of each pod having voltages within 20% of one another and at least one photovoltaic element of each pod having an amperage at least 20% greater than the amperage of another photovoltaic element of the pod.

2. A photovoltaic array according to claim 1, wherein the photovoltaic elements of each pod have voltages within 10% of one another.

3. A photovoltaic array according to claim 1, wherein at least one photovoltaic element of each pod has an amperage at least 50% greater than the amperage of another photovoltaic element of the pod.

4. A photovoltaic array according to claim 1, wherein the pods have amperages within 20% of one another.

5. A photovoltaic array according to claim 1, wherein the photovoltaic elements of differing amperages differ from one another in visual appearance.

6. A photovoltaic array according to claim 5, wherein the photovoltaic elements of differing amperages have different colors, different patterns and/or different surface textures.

7. A photovoltaic array according to claim 1, wherein the photovoltaic elements of differing amperages have different sizes.

8. A photovoltaic array according to claim 1, wherein the photovoltaic elements of differing amperages are disposed on different roofing substrates.

9. A photovoltaic system comprising two or more photovoltaic arrays according to claim 1, wherein the two or more photovoltaic arrays are electrically interconnected in parallel.

10. A photovoltaic roofing element comprising:
a roofing substrate; and
at least one pod of photovoltaic elements, each pod comprising a plurality of photovoltaic elements disposed on the roofing substrate and electrically interconnected in parallel, the photovoltaic elements of each pod having voltages within 20% of one another and at least one photovoltaic element of each pod having an amperage at least 20% greater than the amperage of another photovoltaic element of the pod.

11. A photovoltaic roofing element according to claim 10, wherein the photovoltaic elements of each pod have voltages within 10% of one another.

12. A photovoltaic roofing element according to claim 10, wherein at least one photovoltaic element of each pod has an amperage at least 50% greater than the amperage of another photovoltaic element of the pod.

13. A photovoltaic roofing element according to claim 10, wherein the photovoltaic elements of differing amperages differ from one another in visual appearance.

14. A photovoltaic roofing element according to claim 13, wherein the photovoltaic elements of differing amperages have different colors, different patterns and/or different surface textures.

15. A photovoltaic roofing element according to claim 10, wherein the photovoltaic elements of differing amperages have different sizes.

16. A photovoltaic roofing element according to claim 10, wherein the photovoltaic roofing element comprises two or more pods of photovoltaic elements, the pods of photovoltaic elements being interconnected in series.

17. A photovoltaic array according to claim 16, wherein the pods have amperages within 20% of one another.

18. A photovoltaic roofing element according to claim 10, wherein the roofing substrate is a bituminous shingle.

19. A photovoltaic roofing element according to claim 10, wherein the roofing substrate is polymeric tile, shake or shingle.

20. A photovoltaic roofing array comprising a plurality of photovoltaic roofing elements according to claim 10 electrically interconnected in series.

21. A photovoltaic roofing system comprising a plurality of photovoltaic roofing arrays according to claim 20 electrically interconnected in parallel.

22. A method for making a photovoltaic array, the method comprising:
assembling a plurality of pods of photovoltaic elements, each pod being assembled by interconnecting a plurality of photovoltaic elements in parallel, the photovoltaic elements of each pod having voltages within 20% of one another and at least one photovoltaic element of each pod having an amperage at least 20% greater than the amperage of another photovoltaic element of the pod; then
interconnecting the plurality of pods in series.

23. A method for making a photovoltaic system, the method comprising:
making a plurality of photovoltaic arrays according to the method of claim 22, and interconnecting the plurality of photovoltaic arrays in parallel.

24. A kit for the assembly of a photovoltaic roofing system, comprising
a plurality of roofing substrates;
one or more pluralities of photovoltaic elements, the photovoltaic elements of each plurality having voltages within 20% of one another and at least one photovoltaic element of each plurality having an amperage at least 20% greater than the amperage of another photovoltaic element of the plurality; and
an electrical connection system sufficient to electrically interconnect the one or more pluralities of photovoltaic elements into one or more pods of photovoltaic elements, the photovoltaic elements of each pod having voltages within 20% of one another and at least one photovoltaic element of each pod having an amperage at least 20% greater than the amperage of another photovoltaic element of the pod; and sufficient to electrically interconnect the one or more pods in series.
